(19) United States
(12) Patent Application Publication
(10) Pub. No.: US 2019/0181682 A1
(43) Pub. Date: Jun. 13, 2019

(54) ACTIVE RECTIFIER HAVING MAXIMUM POWER TRANSFER AND MAXIMUM EFFICIENCY OVER DISTANCE

(71) Applicants: ZINITIX CO., LTD., Gyeonggi-do (KR); Res & Business Foundation SUNGKYUNKWAN UNIVERSITY, Gyeonggi-do (KR)

(72) Inventors: Hak Yun KIM, Gyeonggi-do (KR); Kang-Yoon LEE, Seoul (KR); Young-Jun PARK, Gyeonggi-do (KR); Sung-Jin OH, Gyeonggi-do (KR); Sang-Yun KIM, Gyeonggi-do (KR); Byeong-Gi JANG, Gyeonggi-do (KR); Seong-Mun PARK, Gyeongsangnam-do (KR); Ki-Deok KIM, Gyeonggi-do (KR)

(21) Appl. No.: 16/199,372

(22) Filed: Nov. 26, 2018

(30) Foreign Application Priority Data
Dec. 12, 2017 (KR) 10-2017-0170394

(51) Int. Cl. H02J 50/10; H03K 7/08; H02M 7/219

(52) U.S. Cl. CPC H02J 50/10; H02M 2001/0009; H02M 7/219; H03K 7/08

(57) ABSTRACT

Provided is a wireless power reception device including: a gate driver for generating a gate signal for switching between a turn-on voltage and a turn-off voltage; a rectifier connected to both ends of an inductor and including FETs whose on/off states are controlled by the gate signal; a rectifier output detection unit for sensing an output value of the rectifier; and an impedance control unit for controlling an impedance of the rectifier by controlling at least one of a duty ratio of the gate signal and a turn-on voltage for turning on the FET based on the output value.

### CROSS-REFERENCE TO RELATED APPLICATION

This application claims priority to Korean Patent Application No. 10-2017-0170394 filed on Dec. 12, 2017 and all the benefits accruing therefrom under 35 U.S.C. § 119, the contents of which are incorporated by reference in their entirety.

### BACKGROUND

The present invention relates to an active rectifier capable of maximizing power transfer efficiency and maximizing output power by changing the impedance of the active rectifier included in a wireless power reception device.

FIG. 1 shows a wireless charging system using a conventional passive rectifier or active rectifier.

The wireless charging reception system 200 may include a transmission unit 201, a transmission side antenna 261, a reception side antenna 262, an external matching element 203, a passive rectifier or active rectifier 204, and a voltage regulator 205. Here, the transmission unit 201 and the transmission side antenna 261 may be included in the transmission device 240. Then, the reception side antenna 262, the external matching element 203, the passive rectifier or active rectifier 204, and the voltage regulator 205 may be included in the reception device 250. The reception device 250 is distinguished from the transmission device 240. Each of the pair of antennas 261 and 262 may include a coil, for example.

The wireless charging reception system 200 may refer to the transmission device side as a primary side and the reception device side as a secondary side with respect to the antennas 261 and 262. In a wireless charging reception system using a passive rectifier or the conventional active rectifier 204, the impedance seen in the transmission device changes according to the distance d between the transmission device and the reception device. As a result, there is a problem that the power transfer efficiency is lowered as the distance between the transmission device and the reception device increases.

FIG. 2 shows an impedance equivalent circuit of the wireless charging system of FIG. 1. The impedance equivalent circuit may include an impedance 210 of the transmission device and an impedance 211 of the reception device. In the wireless charging reception system, the impedance 210 of the transmission device may vary depending on the distance d between the transmission device and the reception device.

FIG. 3 is a graph showing the relation between the power transfer efficiency and the output power with respect to the impedance, in order to facilitate understanding of the present invention. The horizontal axis represents the impedance (RL/RS), the left vertical axis represents the efficiency, and the right vertical axis represents the output power.

Conventional wireless power transmission systems are designed in such a way that the impedance of the reception device can not be adjusted, so that the variation of the impedance according to the distance between the transmission device and the reception device can not be compensated. Therefore, the output power and efficiency of the reception device are not optimized according to the distance. In order to complement this, another technique for compensating the impedance of the reception device by using an external capacitance matrix or the like has been proposed according to the distance. However, this technique requires additional external components, and as the external device is added, the cost and area increase so that the amount of compensation is limited depending on the external capacitance.

A rectifier including an impedance conversion used in another conventional wireless power transmission system includes a structure for converting a load impedance. Since the conversion of the load impedance is to limit the load current or the voltage, there is a problem that the operation may be restricted depending on the application.

### SUMMARY

As described above, in the wireless power transmission system, the output power and the power transfer efficiency of the reception device are affected by the operation of the circuit, the loss consumed by the circuit, the loss consumed by the antenna, and the loss due to the coupling coefficient of the antenna, which occurs while power is transferred.

In order to minimize the power loss of the circuit, it is necessary to design a small resistance element such that an impedance matching between transmission and reception devices minimizes reactance components and minimizes conduction losses. In relation to this, the distance between the transmission device and the reception device affects the impedance change and greatly affects the power transfer efficiency and output power. If the impedance can be maintained constant according to the distance between transmission device and reception device, high power transfer efficiency and output power can be obtained.

The present invention is to provide a method of varying the impedance of an active rectifier by adjusting a turn-on time of a switch used in an active rectifier, a gate voltage level, and a switch resistance in a rectifier. The present invention provides a wireless power reception device that adjusts the impedance of the active rectifier so as to receive maximum power transfer efficiency or maximum output power by adjusting the impedance according to the distance using the above method.

In accordance with an exemplary embodiment, a wireless power reception device includes: a gate driver 110 for generating a gate signal S_g1 for switching between a turn-on voltage and a turn-off voltage; a rectifier 120 connected to both ends of an inductor 22 and including FETs M1 to M4 whose on/off states are controlled by the gate signal; a rectifier output detection unit 130 for sensing an output value of the rectifier; and an impedance control unit 140 for controlling an impedance of the rectifier by controlling at least one of a duty ratio of the gate signal and a turn-on voltage for turning on the FET based on the output value.

The output value may include an output voltage and an output current of the rectifier, wherein the impedance control unit may maximize a power transfer efficiency between the wireless power reception device and a wireless power transmission device that transmits power to the wireless power reception device or maximize an output power of the wireless power reception device based on the output value.

The gate signal may be a PWM signal provided directly to a gate of the FET, wherein the PWM signal may have one of the turn-off voltage and the turn-on voltage, and a magnitude of the turn-on voltage may be controlled by the impedance control unit.

The impedance control unit may include: a gate voltage adjustment unit 141; a power/efficiency calculation unit 142 for calculating a power transfer efficiency between the wireless power reception device and a wireless power transmission device transmitting power to the wireless power reception device or an output power of the wireless power reception device; and a parameter setting unit 143 for, based on the calculated power transfer efficiency or output power, determining a duty ratio of the gate signal to provide the determined duty ratio to the gate driver and determining a gate voltage level for turning on the FET to provide the determined gate voltage level to the gate voltage adjustment unit, wherein the gate voltage adjustment unit may be configured to adjust the turn-on voltage of the gate signal according to the provided gate voltage level, and the gate driver may output the gate signal so that the duty ratio of the gate signal may have the determined duty ratio.

The rectifier may include four FETs connected in bridge form by the inductor.

An operation power of the gate voltage adjustment unit may be supplied from the rectifier.

The wireless power reception device may further include a voltage regulator for regulating the output of the rectifier.

The rectifier output detection unit may include a voltage detection unit 132 for sensing an output voltage of the rectifier and a current detection unit 131 for sensing an output current of the rectifier, wherein the power/efficiency calculation unit may calculate the power transfer efficiency or calculates the output power using the output voltage sensed by the voltage detection unit and the output current sensed by the current detection unit.

In accordance with another exemplary embodiment, there is a wireless power transfer control method for controlling a transfer efficiency of a wireless power and a maximum power value of a wireless power in an active rectifier including □a gate driver for generating a gate signal for switching between a turn-on voltage and a turn-off voltage, □a rectifier connected to both ends of an inductor and including FETs whose on/off states are controlled by the gate signal, □a rectifier output detection unit for sensing an output value of the rectifier, and □an impedance control unit for controlling an impedance of the rectifier. The method includes: sensing, by the output detection unit, an output voltage and an output current of the rectifier; varying, by the impedance control unit, at least one of the duty ratio of the gate signal and the turn-on voltage that turns the FET on, based on the output voltage and the output current; and determining, by the impedance control unit, the duty ratio and the turn-on voltage to maximize the power transfer efficiency between the active rectifier and a wireless power transmission device transmitting power to the active rectifier or the output power of the active rectifier and maintaining it with the determined value.

The rectifier may include four FETs connected in bridge form by the inductor.

### BRIEF DESCRIPTION OF THE DRAWINGS

Exemplary embodiments can be understood in more detail from the following description taken in conjunction with the accompanying drawings, in which:

FIG. 1 shows a wireless charging system using a conventional passive rectifier or active rectifier;

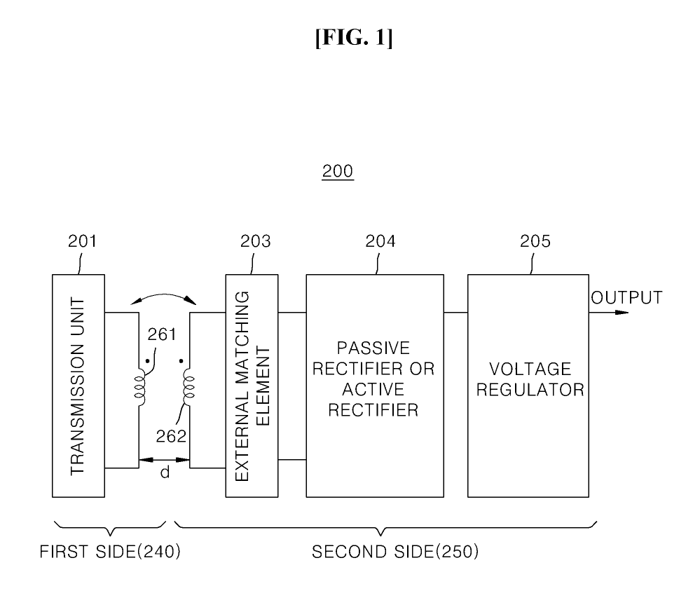

FIG. 2 shows an impedance equivalent circuit of the wireless charging system of FIG. 1;

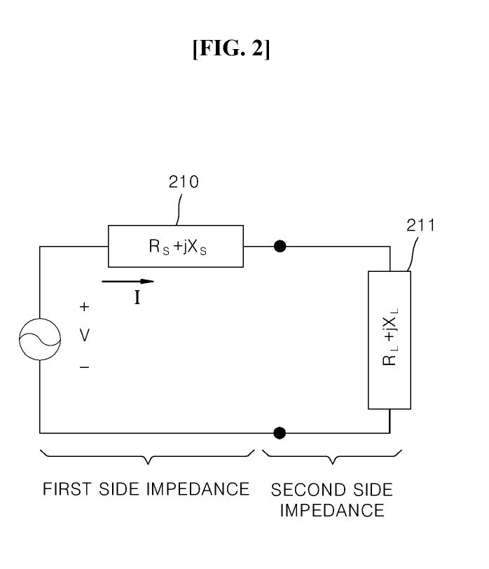

FIG. 3 is a graph showing the relation between the power transfer efficiency and the output power with respect to the impedance, in order to facilitate understanding of the present invention;

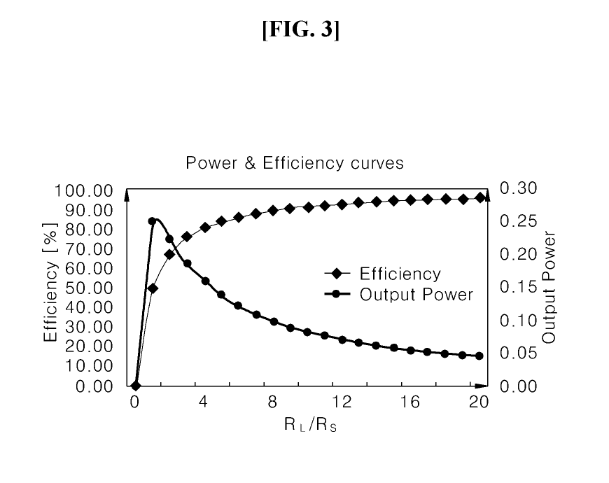

FIG. 4 illustrates a structure for changing the input impedance of a wireless charging reception device without additional external elements according to an embodiment of the present invention;

FIG. 5 is a detailed configuration diagram of the active rectifier of FIG. 4 according to an embodiment of the present invention;

FIG. 6 illustrates an active rectifier for impedance compensation according to an embodiment of the present invention;

FIG. 7 is a timing diagram illustrating an impedance in response to a switching signal of an active device according to an embodiment of the present invention;

FIG. 8 is a graph showing an impedance change amount for a gate-source voltage and an input impedance change amount for a turn-on time/period according to an embodiment of the present invention;

FIG. 9 shows an example of compensating for output power or efficiency according to an embodiment of the present invention;

FIG. 10 illustrates a voltage of a gate signal over time according to another embodiment of the present invention; and

FIG. 11 shows a detailed configuration diagram of an active rectifier according to another embodiment of the present invention.

### DETAILED DESCRIPTION OF EMBODIMENTS

Hereinafter, embodiments of the present invention will be described with reference to the accompanying drawings. However, the present invention is not limited to the embodiments described herein, but may be implemented in various other forms. The terminology used herein is for the purpose of understanding the embodiments and is not intended to limit the scope of the present invention. In addition, the singular forms used below include plural forms unless the phrases expressly have the opposite meaning.

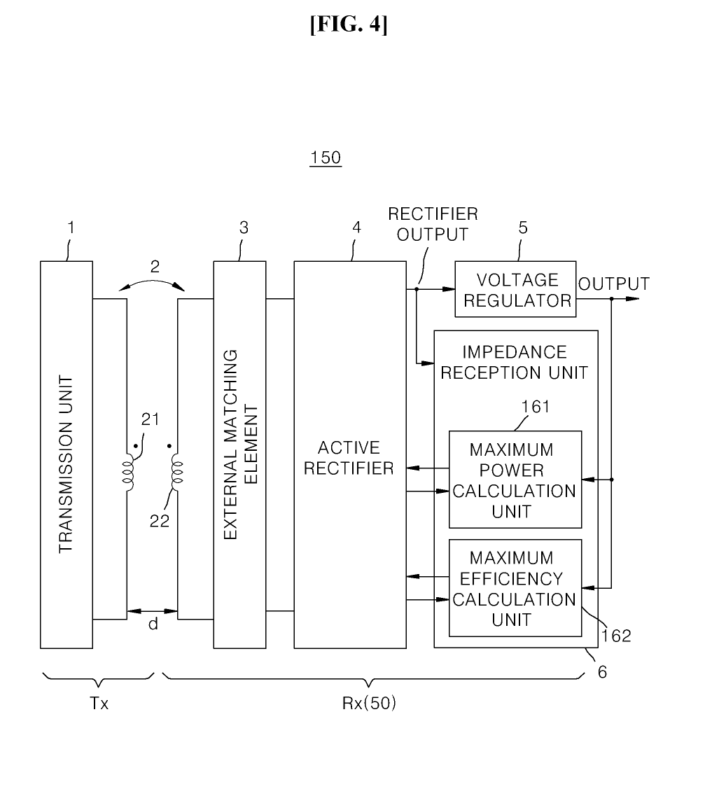

FIG. 4 illustrates a wireless charging reception system 150 according to an embodiment of the present invention.

That is, FIG. 4 includes the structure of a wireless charging reception device 50 according to one embodiment of the present invention, which is designed to change the input impedance of a wireless power reception device without additional external elements.

The wireless charging reception system 150 may include a transmission device 1, an antenna 2, and a wireless charging reception device 50.

The wireless power reception device 50 may include a reception device side antenna of the antenna 2, an external matching element 3, an active rectifier 4, a voltage regulator 5, and an impedance reception unit 6.

The transmission device 1, the antenna 2, and the external matching element 3 may be identical to conventional components.

An active rectifier 4 may be provided in accordance with an embodiment of the present invention and may be one that enables impedance compensation.

The impedance reception unit 6 may include a maximum power calculation unit 161 and a maximum efficiency calculation unit 162.

The power received through the antenna 2 can be rectified by using an active rectifier 4 for impedance compensation. That is, the voltage induced through the antenna 2 can be rectified using the active rectifier 4. Then, finally, an output voltage can be provided through the voltage regulator 5. The impedance reception unit 6 can calculate the maximum output power and the maximum efficiency by sensing the output voltage and current of the voltage regulator 5 or the output voltage and current of the active rectifier 4. The input impedance of the active rectifier 4 can be changed according to the calculated maximum output power and maximum efficiency value. In order to have maximum power or maximum efficiency through the method described above, the input impedance of the active rectifier 4 can be compensated.

As a method of obtaining maximum power, a method may be used in which the current calculated output power is compared with the previously calculated output power to determine whether the current or previous maximum power transfer is performed.

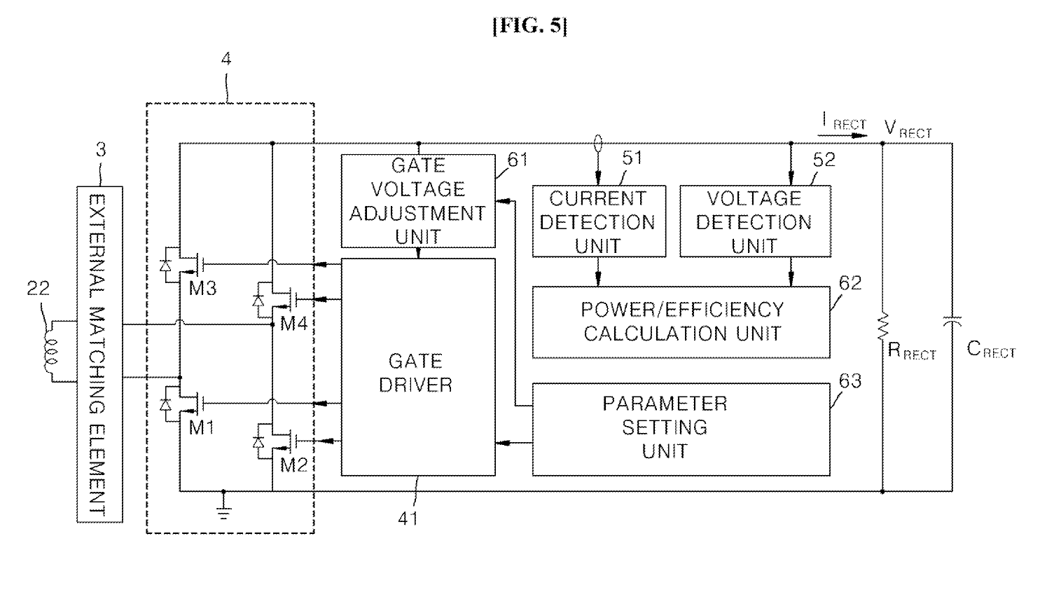

FIG. 5 is a detailed configuration diagram of the wireless power reception device of FIG. 4 according to an embodiment of the present invention.

The wireless power reception device may include an external matching element 3, an active rectifier 4, a gate driver 41, a current detection unit 51, a voltage detection unit 52, a gate voltage adjustment unit 61, a power/efficiency calculation unit 62, and a parameter setting unit 63. The parameter setting unit 63 may perform generation of a gate signal, adjustment of a duty ratio, and setting of a gate voltage level.

The active rectifier 4 may include switch resistors M1, M2, M3, and M4. The switch resistances M1, M2, M3, and M4 may refer to a turn-on resistance.

In one embodiment, the active rectifier 4 may include four FET switches. In this case, the four switch resistors M1, M2, M3, and M4 may be provided by the four FET switches, respectively.

In another embodiment, the active rectifier 4 may include two FET switches and two passive elements. In this case, two of the four switch resistances M1, M2, M3 and M4 may be provided by the two FET switches, and the other two switch resistors may be provided by the two passive elements, respectively.

The gate driver 41 can control on/off of the switch resistance of the rectifier 4 according to the output value of the gate voltage adjustment unit 61. The operation of the gate voltage adjustment unit 61 can be controlled by the parameter setting unit 63.

The load current IRECT and voltage VRECT rectified by the active rectifier 4 can be sensed using the current detection unit 51 and the voltage detection unit 52. The current and voltage sensed by the current detection unit 51 and the voltage detection unit 52 may be referred to as a detection current and a detection voltage, respectively.

The power/efficiency calculation unit 62 can obtain the output power of the active rectifier 4 using the detection voltage and the detection current.

The parameter setting unit 63 may vary the input impedance of the active rectifier 4 by adjusting the turn-on time, gate voltage and/or switch resistance of each of the FET switches included in the active rectifier 4. At this time, by comparing the ‘Current output power’ outputted from the active rectifier 4 according to the changed input impedance with the ‘previous output power’ outputted by the active rectifier 4, the maximum power or maximum efficiency of the active rectifier 4 can be obtained. And, by controlling the gate voltage, it is possible to adjust the impedance as shown below. The turn-on resistance Rₒₙ of the FET switch is inversely proportional to the gate-source voltage V_{GS} of the FET switch as shown in Equation 1 below.

$${R}_{on} ∝ \frac{1}{{V}_{GS} - {V}_{TH}} \qquad [ Equation 1 ]$$

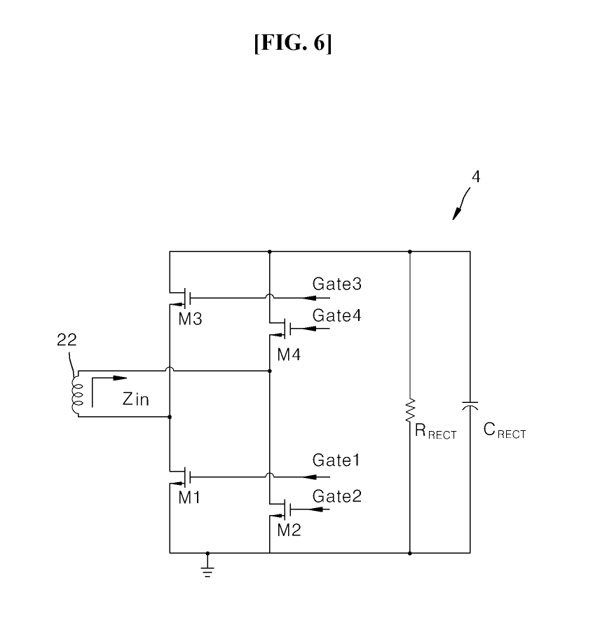

FIG. 6 illustrates an active rectifier for impedance compensation according to another embodiment of the present invention.

In one embodiment, in relation to the active rectifier 4, only the switch resistance M1 and the switch resistance M2 can be active elements. That is, the switch resistance M3 and the switch resistance M4 may be passive elements. At this time, the switch resistance M1 and the switch resistance M2 may be provided by FET switches, respectively.

On the other hand, FIG. 5 shows an embodiment using a switch resistor as a Complementary Metal Oxide Semiconductor (CMOS), and includes all the active elements usable as a switch.

In another embodiment, the active rectifier 4 can be mixed with an active element and a passive element.

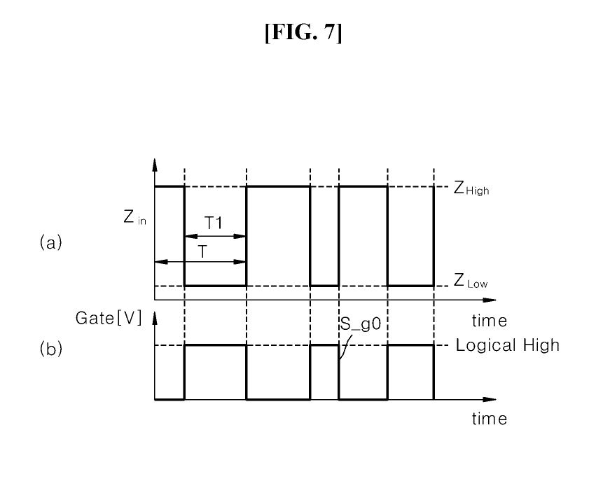

FIG. 7 is a timing diagram illustrating an input impedance in response to a switching signal of an active device according to an embodiment of the present invention.

FIG. 7(a) shows the impedance value with time, and FIG. 7(b) shows the voltage of the gate signal with time.

In FIG. 7(a), the horizontal axis represents time and the vertical axis represents the input impedance of the active rectifier 4. In FIG. 7(b), the horizontal axis represents time and the vertical axis represents the voltage of the gate signal supplied to the gate of the FET device included in the active rectifier 4.

When the gate signal S_g0 is turned on, impedance appears to be small (Z_{Low}), and when the gate signal S_g0 is turned off, since the switch is off, the impedance looks very large (Z_{High}).

In Equation 2 below, referring to FIG. 5, the turn-on resistance of the switch is Ron, and when assuming that the turn-off resistance is infinite, it is the value of the input impedance of the active rectifier 4.

$${Z}_{Low} = ( {R}_{on} + {R}_{RECT} ) PVER \frac{1}{{sC}_{RECT}} \\ {Z}_{High} = ∞ \qquad [ Equation 2 ]$$

Therefore, the input impedance Z₁ during one period of the active rectifier 4 is expressed by Equation 3.

Zᵢₙ=(Z_{Low}×D)+(Z_{High}×(1−D)) [Equation 3]

Then, D is the duty ratio of the gate signal input to the gate of the FET included in the active rectifier 4 and is a value smaller than 1.

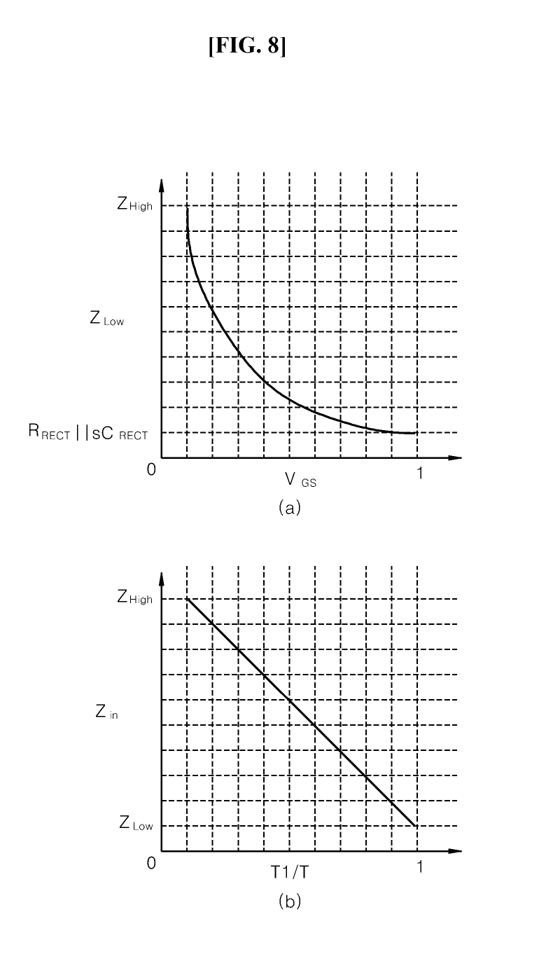

FIG. 8 is a graph showing an impedance change amount Z_{Low} for the gate-source voltage V_{GS} and an input impedance change amount Zᵢₙ of the active rectifier 4 for the turn-on time/period (T1/T) according to an embodiment of the present invention.

FIG. 8(a) shows an impedance change amount Z_{Low} for the gate-source voltage V_{GS} and FIG. 8(b) shows an input impedance change amount Zᵢₙ for the turn-on time/period (T1/T).

The input impedance range that can be changed according to the turn-on time T1 is from Z_{High} to Z_{Low}. More precisely, the driver's gate-source voltage V_{GS} can be used to adjust the input impedance or change the turn-on resistance of the FET switch. Therefore, the input impedance of the active rectifier can be adjusted without using an external device.

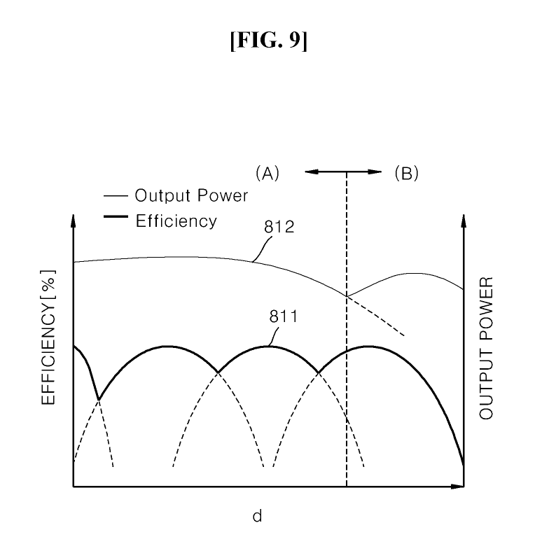

FIG. 9 shows an example of a result of compensating for output power or efficiency according to an embodiment of the present invention.

Reference numeral 811 in FIG. 9 represents power transfer efficiency from a transmission device to a reception device according to a distance between a transmission device and a reception device. Reference numeral 812 in FIG. 9 represents the output power outputted from the reception device according to the distance between the transmission device and the reception device.

That is, FIG. 9 illustrates an effect obtained by the configuration according to an embodiment of the present invention, and illustrates an example of compensating efficiency according to the distance of a transmission/reception device and compensating for output power.

Since the input impedance of the active rectifier 4 varies depending on the distance d between the transmission device and the reception device, a phenomenon that efficiency is rapidly reduced and increased according to the distance is repeated (see reference numeral 811). However, by changing the input impedance of the active rectifier 4, it is possible to find the optimum efficiency.

On the other hand, in situations where the output power of the active rectifier 4 is more important than efficiency, impedance can be varied to obtain maximum power and enable wireless charging at a greater distance (see reference numeral 812).

In the area A of FIG. 9, there is no relatively large change in the output power, but the efficiency greatly changes. Therefore, it may be desirable to control the efficiency in the area A of FIG. 9 rather than optimize the output power. In the area B of FIG. 9, the efficiency decreases sharply with distance. Therefore, it may be desirable to control the output power to be optimized rather than to optimize efficiency in the area B of FIG. 9. However, this control method is according to a preferred embodiment, and the present invention is not necessarily limited to such a method.

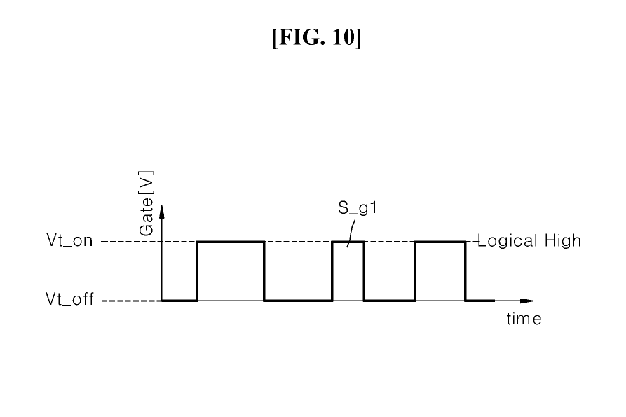

FIG. 10 shows the voltage of the gate signal S_g1 based on time according to an embodiment of the present invention. The gate signal S_g1 may have a waveform in the form of a pulse train, and may be a PWM waveform in particular. The gate signal S_g1 may be a signal provided to the gate of the FET switch included in the active current device 4.

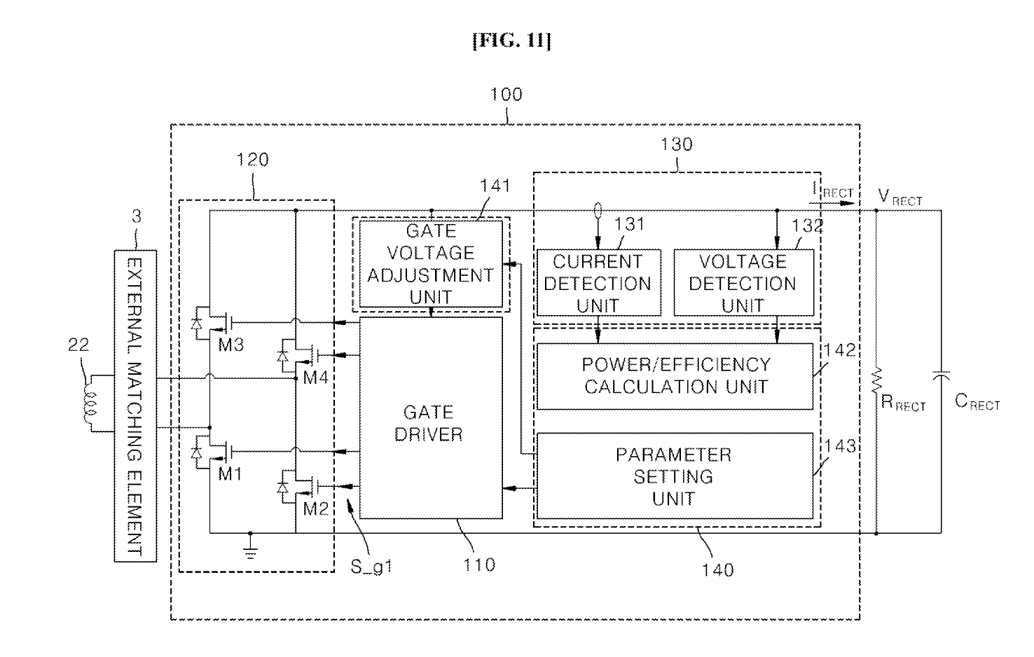

FIG. 11 shows a detailed configuration diagram of a wireless power reception device 100 according to another embodiment of the present invention.

Hereinafter, this will be described with reference to FIGS. 10 and 11.

The wireless power reception device 100 may include a gate driver 110, an active rectifier 120, a rectifier output detection unit 130, and an impedance control unit 140.

The gate driver 110 may generate a gate signal S_g1 that switches between a turn-on voltage and a turn-off voltage.

The active rectifier 120 is connected to both ends of the inductor 22 and may include FETs whose on/off states are controlled by the gate signal S_g1. That is, the active rectifier 120 may include four FETs M1, M2, M3, and M4 connected in the form of a bridge by the inductor 22. At this time, the external matching element 3 may be further connected to both ends of the inductor 22.

The rectifier output detection unit 130 may detect an output value of the active rectifier 120. The output value may include an output voltage and an output current of the active rectifier 120.

The impedance control unit 140 may include a gate voltage adjustment unit 141, a power/efficiency calculation unit 142, and a parameter setting unit 143.

The impedance control unit 140 may control the impedance of the active rectifier 120 by controlling at least one of the duty ratio of the gate signal S_g1 and the turn-on voltage that turns on the FET, based on the output value. At this time, the gate signal S_g1 may be a PWM signal directly provided to the gate of the FET. Then, the PWM signal may have one of the turn-off voltage and the turn-on voltage, and the magnitude of the turn-on voltage may be controlled by the impedance control unit 140.

The power/efficiency calculation unit 142 of the impedance control unit 140 may calculate the power transfer efficiency between the wireless power reception device 100 and the wireless power transmission device transmitting power to the wireless power reception device 100, and the output power of the wireless power reception device. That is, the impedance control unit 140 may maximize the power transfer efficiency between the wireless power reception device 100 and the wireless power transmission device transmitting power to the wireless power reception device 100, and the output power of the wireless power reception device based on the output value of the active rectifier 120.

The output power of the wireless power reception device may be the output power of the active rectifier 120.

The parameter setting unit 143 of the impedance control unit 140 determines the duty ratio of the gate signal S_g1 based on the calculated power transfer efficiency or output power to provide the determined duty ratio to the gate driver 110, and determines the gate voltage level at which the FET is turned on to provide the determined gate voltage level to the gate voltage adjustment unit 141.

The gate voltage adjustment unit 141 may be configured to adjust the turn-on voltage of the gate signal S_g1 according to the provided gate voltage level.

The gate driver 110 may output the gate signal S_g1 such that the duty ratio of the gate signal S_g1 has the determined duty ratio.

The ‘active rectifier’ described herein may be referred to simply as a ‘rectifier’.

According to the present invention, depending on the distance between the wireless charging reception device and the transmission device, the input impedance of the wireless charging reception device can be changed to allow maximum efficiency or maximum power transfer without the addition of external devices. In addition, according to the present invention, since no external element is used, it is advantageous in cost and area reduction, and the impedance compensation can be made finer. In addition, according to the present invention, the power transmission distance can be increased compared with a conventional wireless charging reception device.

It will be apparent to those skilled in the art that various modifications and variations may be made in the present invention without departing from the spirit or essential characteristics thereof. The contents of each claim may be combined with other claims without departing from the scope of the claims.

What is claimed is:

1. A wireless power reception device comprising:
a gate driver 110 for generating a gate signal S_g1 for switching between a turn-on voltage and a turn-off voltage;
a rectifier 120 connected to both ends of an inductor 22 and including FETs M1 to M4 whose on/off states are controlled by the gate signal;
a rectifier output detection unit 130 for sensing an output value of the rectifier; and
an impedance control unit 140 for controlling an impedance of the rectifier by controlling at least one of a duty ratio of the gate signal and a turn-on voltage for turning on the FET based on the output value.

2. The wireless power reception device of claim 1, wherein the output value comprises an output voltage and an output current of the rectifier,
wherein the impedance control unit maximizes a power transfer efficiency between the wireless power reception device and a wireless power transmission device that transmits power to the wireless power reception device or maximizes an output power of the wireless power reception device based on the output value.

3. The wireless power reception device of claim 1, wherein the gate signal is a PWM signal provided directly to a gate of the FET,
wherein the PWM signal has one of the turn-off voltage and the turn-on voltage, and a magnitude of the turn-on voltage is controlled by the impedance control unit.

4. The wireless power reception device of claim 1, wherein the impedance control unit comprises:
a gate voltage adjustment unit 141;
a power/efficiency calculation unit 142 for calculating a power transfer efficiency between the wireless power reception device and a wireless power transmission device transmitting power to the wireless power reception device or an output power of the wireless power reception device; and
a parameter setting unit 143 for, based on the calculated power transfer efficiency or output power, determining a duty ratio of the gate signal to provide the determined duty ratio to the gate driver and determining a gate voltage level for turning on the FET to provide the determined gate voltage level to the gate voltage adjustment unit,
wherein the gate voltage adjustment unit is configured to adjust the turn-on voltage of the gate signal according to the provided gate voltage level, and
the gate driver outputs the gate signal so that the duty ratio of the gate signal has the determined duty ratio.

5. The wireless power reception device of claim 1, wherein the rectifier comprises four FETs connected in bridge form by the inductor.

6. The wireless power reception device of claim 4, wherein an operation power of the gate voltage adjustment unit is supplied from the rectifier.

7. The wireless power reception device of claim 1, further comprising a voltage regulator for regulating the output of the rectifier.

8. The wireless power reception device of claim 4, wherein the rectifier output detection unit comprises a voltage detection unit 132 for sensing an output voltage of the rectifier and a current detection unit 131 for sensing an output current of the rectifier,
wherein the power/efficiency calculation unit calculates the power transfer efficiency or calculates the output power using the output voltage sensed by the voltage detection unit and the output current sensed by the current detection unit.

9. A wireless power transfer control method for controlling a transfer efficiency of a wireless power and a maximum power value of a wireless power in an active rectifier including 1 a gate driver for generating a gate signal for switching between a turn-on voltage and a turn-off voltage, 2 a rectifier connected to both ends of an inductor and including FETs whose on/off states are controlled by the gate signal, 3 a rectifier output detection unit for sensing an output value of the rectifier, and 4 an impedance control unit for controlling an impedance of the rectifier, the method comprising:
sensing, by the output detection unit, an output voltage and an output current of the rectifier;
varying, by the impedance control unit, at least one of the duty ratio of the gate signal and the turn-on voltage that turns the FET on, based on the output voltage and the output current; and
determining, by the impedance control unit, the duty ratio and the turn-on voltage to maximize the power transfer efficiency between the active rectifier and a wireless power transmission device transmitting power to the active rectifier or the output power of the active rectifier and maintaining it with the determined value.

10. The method of claim 9, wherein the rectifier comprises four FETs connected in bridge form by the inductor.
